(19) United States
(12) Patent Application Publication
(10) Pub. No.: US 2024/0222177 A1
(43) Pub. Date: Jul. 4, 2024

(54) SUBSTRATE SUPPORT APPARATUS

(71) Applicant: SEMES CO., LTD., Chungcheongnam-do (KR)

(72) Inventor: Yong PARK, Cheonan-si (KR)

(21) Appl. No.: 18/393,850

(22) Filed: Dec. 22, 2023

(30) Foreign Application Priority Data
Dec. 30, 2022 (KR) 10-2022-0190970

(51) Int. Cl. H01L 21/68; H01L 21/683

(52) U.S. Cl. CPC H01L 21/68; H01L 21/6838

(57) ABSTRACT

A substrate support apparatus includes a first chuck configured to support a substrate by contacting a bottom surface of the substrate, a second chuck configured to horizontally move the substrate by contacting a side surface of the substrate, wherein the second chuck includes a second chuck body coupled to the first chuck, a plurality of protruding pins vertically protruding from an outer portion of a top surface of the second chuck body, and an alignment pin vertically protruding from a top surface of each of the plurality of protruding pins, wherein the plurality of protruding pins are located at a same horizontal distance from a center of the first chuck.

### CROSS-REFERENCE TO RELATED APPLICATION

This application is based on and claims priority under 35 U.S.C. § 119 to Korean Patent Application No. 10-2022-0190970, filed on Dec. 30, 2022, in the Korean Intellectual Property Office, the disclosure of which is incorporated by reference herein in its entirety.

### BACKGROUND

### 1. Field

The disclosure relates to a substrate support apparatus, and more particularly, to a support substrate apparatus for aligning the center of a substrate.

### 2. Description of the Related Art

In general, a semiconductor apparatus is manufactured by forming a certain thin film on a silicon wafer used as a semiconductor substrate and forming a thin film pattern having electrical characteristics from the thin film.

The thin film pattern is formed by sequentially or repeatedly performing unit processes such as chemical deposition, sputtering, photolithography, etching, ion implantation, and chemical mechanical polishing (CMP). In the unit processes, a chuck for supporting and fixing the wafer is used. As single-wafer processing and dry processing are preferred in a wafer processing technology for miniaturization and large capacity of semiconductor apparatuses, a method of fixing the wafers is also greatly changing.

Also, the center of a substrate is required to be constantly aligned to correspond to a bevel process of the substrate.

### SUMMARY

Provided is a substrate support apparatus for precisely aligning a substrate.

Also, technical objectives to be achieved by the disclosure are not limited thereto, and other technical objectives will be apparent to one of ordinary skill in the art from the description of the disclosure.

Additional aspects will be set forth in part in the description which follows and, in part, will be apparent from the description, or may be learned by practice of the presented embodiments.

According to an aspect of the disclosure, a substrate support apparatus is provided.

The substrate support apparatus includes a first chuck configured to support a substrate by contacting a bottom surface of the substrate, and a second chuck configured to horizontally move the substrate by contacting a side surface of the substrate, wherein the second chuck includes a second chuck body coupled to the first chuck, a plurality of protruding pins vertically protruding from an outer portion of a top surface of the second chuck body, and an alignment pin vertically protruding from a top surface of each of the plurality of protruding pins, wherein the plurality of protruding pins are located at a same horizontal distance from a center of the first chuck.

The alignment pin may be configured to move between a first point and a second point on the top surface of the protruding pin, wherein the second points on the top surfaces of the plurality of protruding pins are located at a same horizontal distance from the center of the first chuck.

The alignment pin may move between the first point and the second point due to a rotation of the protruding pin.

The alignment pin may move horizontally between the first point and the second point in a sliding manner on the top surface of the protruding pin.

The alignment pin may move the substrate by pushing a side surface of the substrate while moving from the first point to the second point.

The substrate support apparatus may further include an impact absorbing pad formed on a side surface of the alignment pin.

The second chuck body may have a cylindrical shape that vertically extends.

The second chuck body may include a plurality of arms that extend horizontally.

The second chuck may further include a height adjusting unit configured to vertically move the second chuck body.

Three protruding pins may be provided, wherein the three protruding pins are located along vertices of a virtual equilateral triangle on the top surface of the second chuck body.

The first chuck may be a vacuum chuck using vacuum to attach the bottom surface of the substrate.

According to another aspect of the disclosure, a substrate support apparatus is provided.

The substrate support apparatus includes a first chuck configured to support a substrate by contacting a bottom surface of the substrate, a second chuck configured to horizontally move the substrate by contacting a side surface of the substrate, the second chuck including a second chuck body coupled to the first chuck, a plurality of protruding pins vertically protruding from an outer portion of a top surface of the second chuck body, and an alignment pin vertically protruding from a top surface of each of the plurality of protruding pins, and a height adjusting unit configured to vertically move the second chuck, wherein the plurality of protruding pins are located at a same horizontal distance from a center of the first chuck, and the alignment pin is configured to move between a first point and a second point on the top surface of the protruding pin, wherein the second points on the top surfaces of the plurality of protruding pins are located at a same horizontal distance from the center of the first chuck, and the alignment pin moves the substrate by pushing a side surface of the substrate while moving from the first point to the second point.

The alignment pin may move between the first point and the second point due to rotation of the protruding pin.

The alignment pin may move horizontally between the first point and the second point in a sliding manner on the top surface of the protruding pin.

The substrate support apparatus may further include an impact absorbing pad formed on a side surface of the alignment pin, wherein the impact absorbing pad is formed only on a side surface of the alignment pin facing a side surface of the substrate.

The second chuck body may have a cylindrical shape that vertically extends.

Three protruding pins may be provided, wherein the three protruding pins are located along vertices of a virtual triangle on the top surface of the second chuck body.

According to another aspect of the disclosure, a substrate support apparatus is provided.

The substrate support apparatus includes a first chuck comprising a support plate configured to support a substrate and a driving unit configured to drive the support plate, the support plate contacting a bottom surface of the substrate, a second chuck contacting a side surface of the substrate to horizontally move the substrate, the second chuck including a second chuck body coupled to the driving unit of the first chuck, a plurality of protruding pins vertically protruding from an outer portion of a top surface of the second chuck body, and an alignment pin vertically protruding from a top surface of each of the plurality of protruding pins, and a height adjusting unit configured to vertically move the second chuck, wherein the plurality of protruding pins include at least three protruding pins and are located at a same horizontal distance from a center of the first chuck, and the alignment pin is configured to move between a first point and a second point on the top surface of the protruding pin, wherein the second points on the top surfaces of the plurality of protruding pins are located at a same horizontal distance from the center of the first chuck, and an impact absorbing pad is formed on a side surface of the alignment pin.

The alignment pin may move between the first point and the second point due to rotation of the protruding pin.

The alignment pin may move horizontally between the first point and the second point in a sliding manner on the top surface of the protruding pin.

### BRIEF DESCRIPTION OF THE DRAWINGS

The above and other aspects, features, and advantages of certain embodiments will be more apparent from the following description taken in conjunction with the accompanying drawings, in which:

FIG. 1 is a plan view schematically illustrating substrate processing equipment, according to an embodiment;

FIG. 2 is a view illustrating the substrate processing equipment of FIG. 1, taken along line A-A;

FIG. 3 is a plan view schematically illustrating substrate cleaning equipment, according to an embodiment;

FIG. 4 is a cross-sectional view schematically illustrating a substrate support apparatus, according to embodiments;

FIG. 5A is a perspective view schematically illustrating an alignment member of the substrate support apparatus of FIG. 4;

FIGS. 5B and 5C are perspective views for describing an alignment method of an alignment member, according to embodiments;

FIGS. 6A to 6C are plan views for describing an alignment method of an alignment member, according to embodiments;

FIG. 7 is a plan view schematically illustrating a second chuck, according to embodiments; and

FIG. 8 is a plan view schematically illustrating a second chuck, according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The same elements are denoted by the same reference numerals in the drawings, and thus, a repeated description thereof will be omitted.

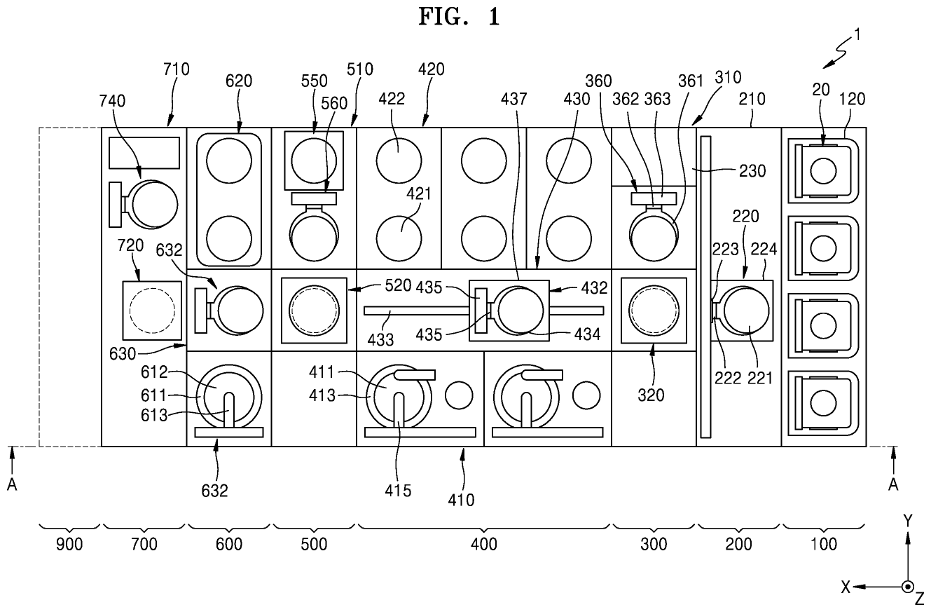

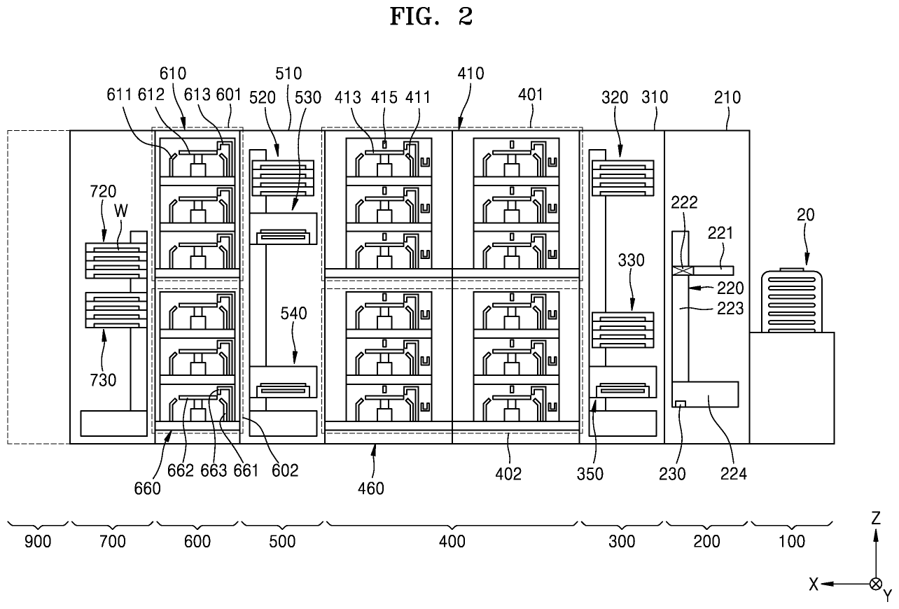

FIG. 1 is a plan view schematically illustrating substrate processing equipment 1, according to an embodiment. FIG. 2 is a schematic view illustrating the substrate processing equipment 1 of FIG. 1, taken along line A-A.

Referring to FIGS. 1 and 2, the substrate processing equipment 1 includes a load port 100, an index module 200, a first buffer module 300, an application and development module 400, a second buffer module 500, a pre- and post-exposure processing module 600, and an interface module 700. The load port 100, the index module 200, the first buffer module 300, the application and development module 400, the second buffer module 500, the pre- and post-exposure processing module 600, and the interface module 700 are sequentially aligned in one direction.

In the accompanying drawings, a direction in which the load port 100, the index module 200, the first buffer module 300, the application and development module 400, the second buffer module 500, the pre- and post-exposure processing module 600, and the interface module 700 are arranged is referred to as a first horizontal direction X, a direction perpendicular to the first horizontal direction X when viewed from above is referred to as a second horizontal direction Y, and a direction perpendicular to the first horizontal direction X and the second horizontal direction Y is referred to as a vertical direction Z.

The load port 100 may include a cassette 20 and a mounting table 120. The cassette 20 may be configured to accommodate a substrate W therein. The substrate W is moved while being accommodated in the cassette 20. In this case, the cassette 20 may have a structure that may be sealed from the outside. For example, a front open unified pod (FOUP) having a door in the front may be used as the cassette 20. A plurality of substrates W may be accommodated in the cassette 20. The cassette 20 in which the substrates W are accommodated may be located on a top surface of the mounting table 120. A plurality of mounting tables 120 are provided, and the mounting tables 120 are aligned in the second horizontal direction Y.

The index module 200 may be configured to transfer the substrate W between the load port 100 and the first buffer module 300. The index module 200 may include a frame 210, an index robot 220, and a guide rail 230. The frame 210 is provided in a rectangular parallelepiped shape with an empty inside, and is located between the load port 100 and the first buffer module 300. The index robot 220 and the guide rail 230 are located in the frame 210. The index robot 220 may include a hand 221, an arm 222, a support 223, and a base 224. The index robot 220 may be configured so that the hand 221 that directly handles the substrate W is movable in the first horizontal direction X, the second horizontal direction Y, and the vertical direction Z and is rotatable on an X-Y plane using the vertical direction Z as a rotational axis. The hand 221 may be fixed to the arm 222, and the arm 222 may be provided as a stretchable and rotatable structure, and may be coupled to the support 223 to be movable along the support 223. The support 223 may be fixedly coupled to the base 224. The guide rail 230 may be provided so that a longitudinal direction is the second horizontal direction Y, and the base 224 may be coupled to the guide rail 230 to be linearly movable along the guide rail 230. Also, although not shown, a door opener for opening and closing a door of the cassette 20 may be further provided in the frame 210.

The first buffer module 300 may include a frame 310, a first buffer 320, a second buffer 330, a cooling chamber 350, and a first buffer robot 360. The frame 310 may provide a space in which the first buffer 320, the second buffer 330, the cooling chamber 350, and the first buffer robot 360 may be located, and the cooling chamber 350, the second buffer 330, and the first buffer 320 are sequentially arranged in the vertical direction Z from the bottom. The first buffer 320 is located at a height corresponding to an application module 401 of the application and development module 400 described below, and the second buffer 330 and the cooling chamber 350 are located at a height corresponding to a development module 402 of the application and development module 400 described below. Each of the first buffer 320 and the second buffer 330 may temporarily store a plurality of substrates W. The first buffer robot 360 includes a hand 361, an arm 362, and a support 363, and may transfer the substrate W between the first buffer 320 and the second buffer 330. The cooling chamber 350 may be configured to cool the substrate W. The cooling chamber 350 may include a cooling means, and may use any of various methods such as cooling using cooling water or cooling using a thermoelectric device.

The application and development module 400 performs a process of applying a photoresist to the substrate W before an exposure process and a process of developing the substrate W after the exposure process. The application and development module 400 includes the application module 401 and the development module 402. The application module 401 and the development module 402 are located to be divided into layers between each other. For example, the application module 401 is located on the development module 402.

The application module 401 may perform a process of applying a photosensitive solution such as a photoresist to the substrate W and a heat treatment process on the substrate W before and after the resist application process. The heat treatment process includes a process of heating and cooling the substrate W. The application module 401 may include a photoresist application chamber 410, a bake chamber 420, and a transfer chamber 430. The photoresist application chamber 410, the transfer chamber 430, and the bake chamber 420 may be sequentially arranged in the second horizontal direction Y. A plurality of photoresist application chambers 410 may be provided, and may be arranged in each of the first horizontal direction X and the vertical direction Z. A plurality of bake chambers 420 may be arranged in each of the first horizontal direction X and the vertical direction Z.

The transfer chamber 430 is located parallel to the first buffer 320 of the first buffer module 300 in the first horizontal direction X. An application unit robot 432 and a guide rail 433 are located in the transfer chamber 430. The application unit robot 432 includes a hand 434, an arm 435, a support 436, and a base 437, and transfers the substrate W between the bake chambers 420, the photoresist application chambers 410, the first buffer 320 of the first buffer module 300, and a first cooling chamber 530 of the second buffer module 500.

The photoresist application chambers 410 may have the same structure. However, types of photosensitive solutions used in the photoresist application chambers 410 may be different from each other. For example, a chemical amplification resist may be used as a photosensitive solution. The photoresist application chamber 410 may be configured to apply a photosensitive solution to the substrate W. The photoresist application chamber 410 may include a housing 411, a support plate 413, and a nozzle 415. The housing 411 has a cup shape with an open top. The support plate 413 is located in the housing 411 to support the substrate W. The support plate 413 is rotatably provided. The nozzle 415 supplies a photosensitive solution to the substrate W placed on the support plate 413. The nozzle 415 may have a circular tube shape, and may supply a photosensitive solution to the center of the substrate W. Optionally, the nozzle 415 may have a length corresponding to a diameter of the substrate W, and an outlet of the nozzle 415 may be a slit. Also, additionally, to clean a surface of the substrate W to which the photosensitive solution is applied, a nozzle through which a cleaning solution such as deionized water is supplied may be further provided in the photoresist application chamber 410.

The bake chamber 420 performs heat treatment on the substrate W. The bake chamber 420 performs heat treatment on the substrate W before and after the photosensitive solution is applied. The bake chamber 420 includes a cooling stage 421 and a heating unit 422. The cooling stage 421 cools the substrate W on which heat treatment is performed by the heating unit 422. The cooling stage 421 is provided in a circular plate shape. A cooling means such as cooling water or a thermoelectric device is provided in the cooling stage 421.

The development module 402 includes a development process of removing a part of a photoresist by supplying a development solution to obtain a pattern on the substrate W and a heat treatment process such as heating and cooling performed on the substrate W before and after the development process. The development module 402 includes a development chamber 460, a bake chamber (not shown), and a transfer chamber (not shown). The development chamber 460, the transfer chamber, and the bake chamber are sequentially arranged in the second horizontal direction Y. A plurality of development chambers 460 are provided, and are arranged in each of the first horizontal direction X and the vertical direction Z.

The development chambers 460 have the same structure. However, types of development solutions used in the development chambers 460 may be different from each other. The development chamber 460 removes a portion of the photoresist on the substrate W to which light is emitted. In this case, a portion of a protective film to which light is emitted is also removed. Optionally, according to a type of a photoresist that is used, only a portion to which light is not emitted from among portions of the photoresist and the protective film may be removed.

The second buffer module 500 is provided as a path through which the substrate W is transported between the application and development module 400 and the pre- and post-exposure processing module 600. Also, the second buffer module 500 performs a certain process such as a cooling process or an edge exposure process on the substrate W. The second buffer module 500 includes a frame 510, a buffer 520, the first cooling chamber 530, a second cooling chamber 540, an edge exposure chamber 550, and a second buffer robot 560. The buffer 520, the first cooling chamber 530, the second cooling chamber 540, the edge exposure chamber 550, and the second buffer robot 560 are located in the frame 510. The buffer 520, the first cooling chamber 530, and the edge exposure chamber 550 are located at a height corresponding to the application module 401. The second cooling chamber 540 is located at a height corresponding to the development module 402. The second buffer robot 560 transports the substrate W between the buffer 520, the first cooling chamber 530, and the edge exposure chamber 550. The second buffer robot 560 may be located between the edge exposure chamber 550 and the buffer 520, and may have a structure similar to that of the first buffer robot 360.

The first cooling chamber 530 and the edge exposure chamber 550 perform a subsequent process on the substrates W on which a process has bee performed in the application module 401. The first cooling chamber 530 cools the substrate W on which a process has been performed in the application module 401, and the edge exposure chamber 550 exposes an edge of the substrates W on which a cooling process has been performed in the first cooling chamber 530. The buffer 520 temporarily stores the substrates W before the substrates W on which a process has been performed in the edge exposure chamber 550 are transported to a pre-processing module 601 described below. The second cooling chamber 540 cools the substrates W before the substrates W on which a process has been performed in a post-processing module 602 described below are transported to the development module 402.

When an exposure device 900 performs an immersion exposure process, the pre- and post-exposure processing module 600 may perform a process of applying a protective film for protecting a photoresist film applied to the substrate W during immersion exposure. Also, the pre- and post-exposure processing module 600 may perform a process of cleaning the substrate W after exposure. Also, when a coating process is performed by using a chemical amplification resist, the pre- and post-exposure processing module 600 may perform a baking process after exposure.

The pre- and post-exposure processing module 600 includes the pre-processing module 601 and the post-processing module 602. The pre-processing module 601 performs a process of processing the substrate W before the exposure process, and the post-processing module 602 performs a process of processing the substrate W after the exposure process.

The pre-processing module 601 includes a protective film application chamber 610, a bake chamber 620, and a transfer chamber 630. A pre-processing robot 632 is located in the transfer chamber 630, and the pre-processing robot 632 transfers the substrate W between the protective film application chambers 610, the bake chambers 620, the buffer 520 of the second buffer module 500, and a first buffer 720 of the interface module 700 described below.

The protective film application chamber 610 applies a protective film for protecting a resist film to the substrate W during immersion exposure. The protective film application chamber 610 includes a housing 611, a support plate 612, and a nozzle 613. The nozzle 613 supplies a protective solution for forming a protective film to the substrate W placed on the support plate 612. The protective solution includes a foamable material. A material having low affinity for water and a photoresistor may be used as the protective solution. For example, the protective solution may include a fluorine-based solvent. The bake chamber 620 performs heat treatment on the substrate W to which the protective film is applied.

Th post-processing module 602 includes a cleaning chamber 660, a post-exposure bake chamber (not shown), and a transfer chamber (not shown). A post-processing robot (not shown) is located in the transfer chamber, and transports the substrate W between the cleaning chambers 660, the post-exposure bake chambers, the second cooling chamber 540 of the second buffer module 500, and a second buffer 730 of the interface module 700 described below. The post-processing robot 682 provided in the post-processing module 602 may have the same structure as that of the pre-processing robot 632 provided in the pre-processing module 601.

The cleaning chamber 660 cleans the substrate W after the exposure process. The cleaning chamber 660 includes a housing 661, a support plate 662, a supply line 664, and a nozzle 663. The housing 661 has a cup shape with an open top. The nozzle 663 supplies a cleaning solution to the substrate W placed on the support plate 662. Water such as deionized water may be used as the cleaning solution. The cleaning chamber 660 supplies the cleaning solution to a central portion of the substrate W while rotating the substrate W placed on the support plate 662. A post-exposure bake chamber 670 heats the substrate W on which the exposure process has been performed by using far ultraviolet rays.

The interface module 700 transfers the substrate W between the pre- and post-exposure processing module 600 and the exposure device 900. The interface module 700 includes a frame 710, the first buffer 720, the second buffer 730, and an interface robot 740. The first buffer 720 is located at a height corresponding to the pre-processing module 601, and the second buffer 730 is located at a height corresponding to the post-processing module 602. The interface robot 740 is spaced apart from the first buffer 720 and the second buffer 730 in the second horizontal direction Y. The interface robot 740 transports the substrate W between the first buffer 720, the second buffer 730, and the exposure device 900. The interface robot 740 has a structure that is substantially similar to that of the second buffer robot 560.

The first buffer 720 temporarily stores the substrates W before the substrates W on which a process has been performed in the pre-processing module 602 are moved to the exposure device 900. The second buffer 730 temporarily stores the substrates W before the substrates W on which a process has been completed in the exposure device 900 are moved to the post-processing module 602.

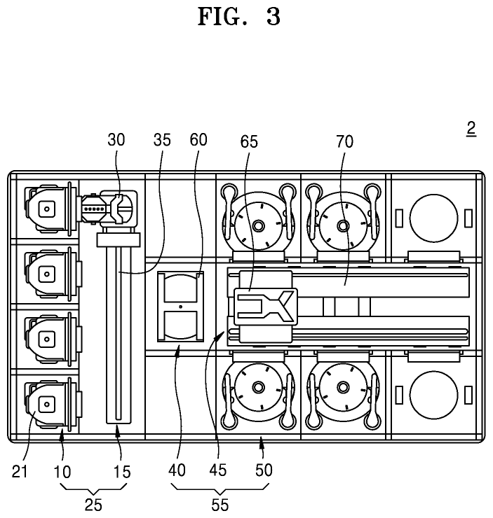

FIG. 3 is a plan view schematically illustrating substrate cleaning equipment, according to an embodiment.

Referring to FIG. 3, substrate cleaning equipment 2 may include an index module 25 and a processing module 55. The index module 25 may transfer a substrate from the outside into the processing module 55, and the processing module 55 may perform desired processes on the substrate. In some embodiments, the processing module 55 may perform a cleaning process on the substrate. The substrate may be a substrate used to manufacture a display apparatus including a flat panel display apparatus or an integrated circuit device including a semiconductor device. Examples of the substrate may include a silicon wafer, a glass substrate, and an organic substrate.

The index module 25 may include a load chamber 10 and a transfer frame 15. A carrier 21 in which the substrate may be accommodated may be loaded in the load chamber 10. For example, a front opening unified pod (FOUP) may be used as the carrier 21. The carrier 21 may be transferred from the outside into the load chamber 10 by an overhead transfer (OHT), and may be transferred from the load chamber 10 to the outside.

The transfer frame 15 may transfer the substrate between the processing module 55 and the carrier 21 loaded in the load chamber 10. The transfer frame 15 may include an index robot 30 and an index rail 35.

The index robot 30 may move along the index rail 35, and may transfer the substrate between the index module 25 and the processing module 55. For example, the index robot 30 may transfer the substrate between the carrier 21 and the buffer slot 60 while moving on the index rail 35.

The substrate transferred between the index module 25 and the processing module 55 may be temporarily placed in a buffer chamber 40. A buffer slot 60 in which the substrate may be placed may be located in the buffer chamber 40. In embodiments, a plurality of buffer slots 60 may be provided in the buffer chamber 40, and thus, a plurality of substrates may be located in the buffer chamber 40.

A transfer chamber 45 may transfer the substrate between the buffer chamber 40 and a cleaning module 50. The transfer chamber 45 may include a transfer robot 65 and a transfer rail 70. The transfer robot 65 may move along the transfer rail 70, and may transfer the substrate between the buffer chamber 40 and the cleaning module 50. For example, the transfer robot 65 may transfer the substrate(s) located in the buffer slot 60 into the cleaning module 50 while moving on the transfer rail 70.

A substrate support apparatus according to the technical spirit of the disclosure will be described. The substrate support apparatus may correspond to a support plate included in the substrate processing equipment 1 and the substrate cleaning equipment 2 described with reference to FIGS. 1 to 3. However, the disclosure is not limited thereto, and the substrate support apparatus may be an apparatus supporting a substrate included in a substrate inspection device or a substrate bonding device.

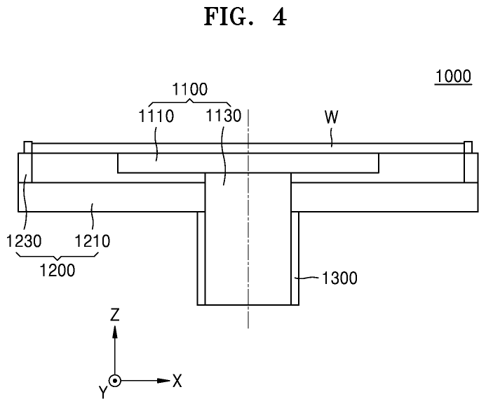

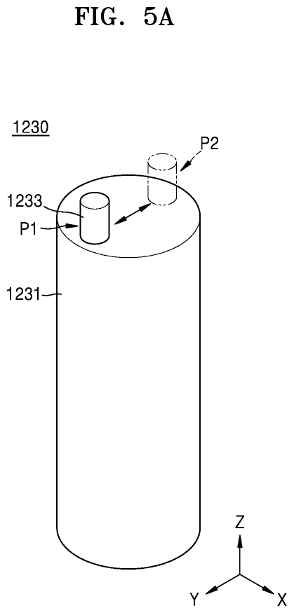

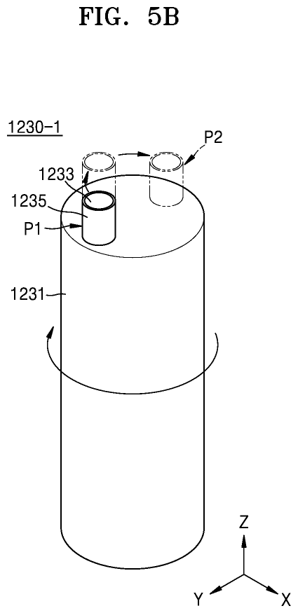

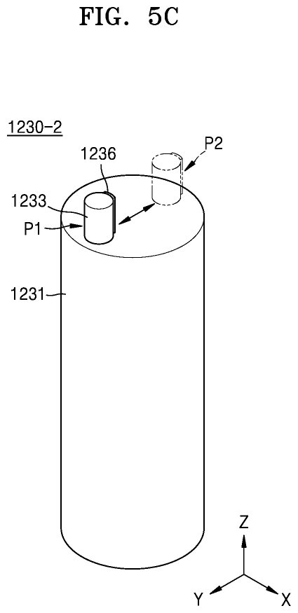

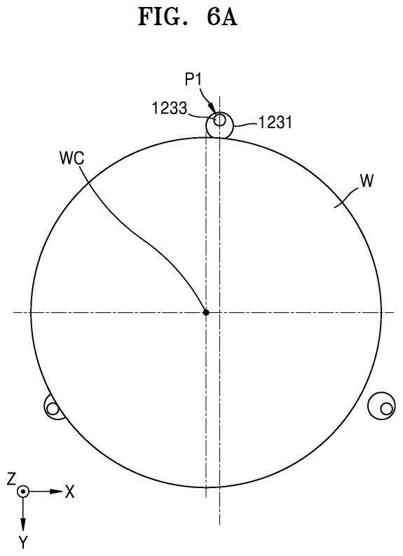

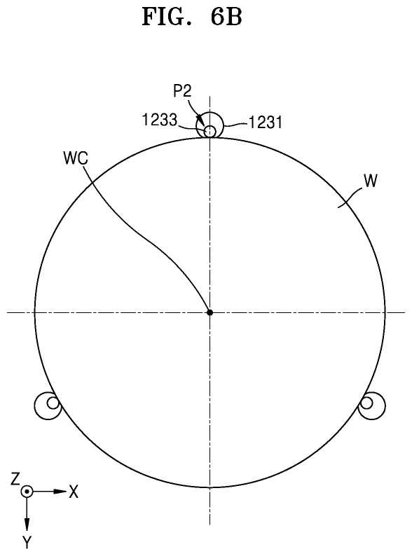

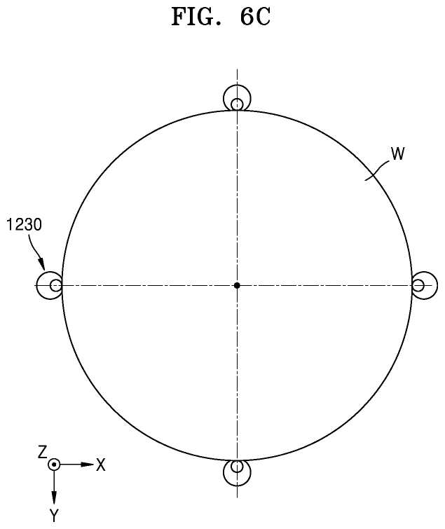

FIG. 4 is a cross-sectional view schematically illustrating a substrate support apparatus, according to embodiments. FIG. 5A is a perspective view schematically illustrating an alignment member of the substrate support apparatus of FIG. 4. FIGS. 5B and 5C are perspective views for describing an alignment method of an alignment member, according to embodiments. FIGS. 6A to 6C are plan views for describing an alignment method of an alignment member, according to embodiments.

Referring to FIGS. 4 to 6C, a substrate support apparatus 1000 may include a first chuck 1100 and a second chuck 1200. The first chuck 1100 may include a support plate 1110 and a driving unit 1130.

The support plate 1110 may directly contact a bottom surface of the substrate W to support the substrate W. According to embodiments, the support plate 1110 may have a flat plate shape extending in a horizontal direction X. The driving unit 1130 may be coupled to a bottom surface of the support plate 1110 to drive the support plate 1110. According to embodiments, the driving unit 1130 may move the support plate 1110 in a vertical direction Z, or may rotate the support plate 1110 around a vertical axis.

According to embodiments, the first chuck 1100 may be a vacuum chuck that uses vacuum to attach the bottom surface of the substrate W to a top surface of the support plate 1110. However, the disclosure is not limited thereto, and the first chuck 1100 may be any chuck as long as it supports the substrate W.

The second chuck 1200 may be coupled to the first chuck 1100. The second chuck 1200 may include a second chuck body 1210 and an alignment member 1230. According to embodiments, the second chuck body 1210 may be coupled to the first chuck 1100. For example, the second chuck body 1210 may be coupled to the driving unit 1130 of the first chuck 1100.

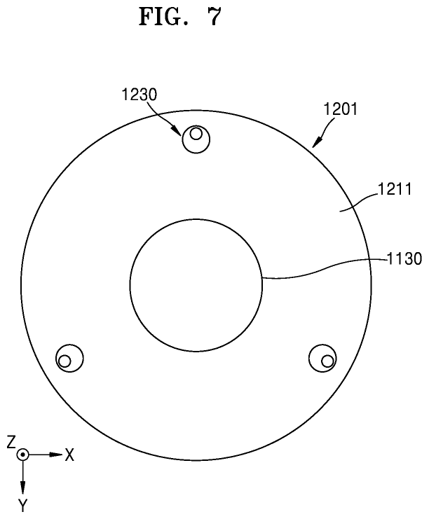

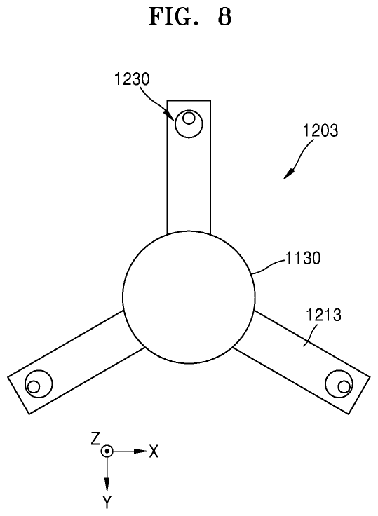

A shape of the second chuck body 1210 will be described below with reference to FIGS. 7 and 8.

The alignment member 1230 may be provided on a top surface of the second chuck body 1210. The alignment member 1230 may include a protruding pin 1231 and an alignment pin 1233 as shown in FIGS. 5A to 5C.

The protruding pin 1231 may be located at an uppermost position of a top surface of the second chuck body 1210. That is, the protruding pin 12131 may be located at an outer portion of the top surface of the second chuck body 1210. A plurality of protruding pins 1231 may be provided. According to embodiments, at least three protruding pins 1231 may be provided.

When at least three protruding pins 1231 are provided, the center of the substrate W and the center of the first chuck 1100 may be aligned with each other as described below.

According to embodiments, the plurality of protruding pins 1231 may be located at the same horizontal distance from the center of the first chuck 1100. For example, when three protruding pins are provided, the protruding pins 1231 may be located on the top surface of the second chuck body 1210 along vertices of a virtual equilateral triangle.

However, the number of protruding pins 1231 is not limited thereto, and four protruding pins 1231 may be provided as shown in FIG. 6C, or four or more protruding pins may be provided.

According to embodiments, a horizontal distance between the center of the protruding pin 1231 and the center of the first chuck 1100 may be substantially the same as or similar to a radius of the substrate W. In some embodiments, when the substrate W is located on the first chuck 1100, a part of a top surface of the protruding pin 1231 may overlap the substrate W in the vertical direction Z. That is, the protruding pin 1231 may be located at a horizontal distance away from the center of the first chuck 1100 to overlap the substrate W in the vertical direction Z.

The protruding pin 1231 may have a cylindrical shape extending in the vertical direction Z. However, the disclosure is not limited thereto, and the protruding pin 1231 may have a prismatic shape extending in the vertical direction Z.

The alignment pin 1233 may be located on the top surface of the protruding pin 1231. The alignment pin 1233 may be located at a certain horizontal distance away from the center of the top surface of the protruding pin 1231. That is, the alignment pin 1233 may be located at a position other than the center of the top surface of the protruding pin 1231.

The alignment pin 1233 may be provided on the top surface of each of the plurality of protruding pins 1231. Accordingly, the number of alignment pins 1233 may be the same as the number of protruding pins 1231.

According to embodiments, the alignment pin 1233 may have a cylindrical shape extending in the vertical direction Z. However, the disclosure is not limited thereto, and the alignment pin 1233 may have a prismatic shape extending in the vertical direction Z.

According to embodiments, the alignment pin 1233 may be configured to be movable on the top surface of the protruding pin 1231. For example, as shown in FIG. 5A, the alignment pin 1233 may move between a first point P1 and a second point P2.

The first point P1 and the second point P2 may each be a point on the top surface of the protruding pin 1231. FIG. 6A is a view illustrating a state where the alignment pin 1233 is located at the first point P1. FIG. 6B is a view illustrating a state where the alignment pin 1233 is located at the second point P2. As shown in FIGS. 6A and 6B, the alignment pin 1233 may move between the first point P1 and the second point P2 of the protruding pin 1231.

According to embodiments, as shown in FIGS. 6A and 6B, the first point P1 may be located far from the substrate W on a top surface of the protruding pin 1231, and the second point P2 may be located close to the substrate W on the top surface of the protruding pin 1231.

A height adjusting unit 1300 may move the second chuck body 1210 in the vertical direction Z. That is, the height adjusting unit 1300 may move the second chuck body 1210 up and down in the vertically direction. As the height adjusting unit 1300 moves the body in the vertical direction Z, the alignment member 1230 may also move in the vertical direction Z.

The alignment member 1230 may be moved by the height adjusting unit 1300 until the top surface of the protruding pin 1231 of the alignment member 1230 is on the same plane as a top surface of the support plate 1110 of the first chuck 1100. That is, when the top surface of the protruding pin 1231 of the alignment member 1230 is on the same plane as the top surface of the support plate 1110 of the first chuck 1100, the alignment member 1230 may move to a maximum height in the vertical direction Z. Also, the alignment member 1230 may be moved downward by the height adjusting unit 1300 in the vertical direction Z

When the alignment member 1230 moves to the maximum height in the vertical direction z, a side surface of the alignment pin 1233 and a side surface of the substrate W may face each other. In other words, when the alignment member 1230 moves to the maximum height in the vertical direction Z, a side surface of the alignment pin 1233 and a side surface of the substrate W may overlap each other in the horizontal direction X.

After the alignment member 1230 moves to the maximum height in the vertical direction Z, the alignment pin 1233 may move between the first point P1 and the second point P2.

In this case, as shown in FIG. 6A, the substrate W may be located on the first chuck 1100 in a state where a center WC of the substrate W does not match the center of the first chuck 1100. That is, the center WC of the substrate W located on the first chuck 1100 may not match the center of the first chuck 1100.

In this case, when the alignment pin 1233 moves from the first point P1 to the second point P2, as shown in FIG. 6B, the alignment pin 1233 may horizontally push a side surface of the substrate W so that the substrate W is horizontally moved and the center WC of the substrate W finally matches the center of the first chuck 1100.

Also, as shown in FIG. 6C, four alignment members may be provided to form 90 degrees. Even in this case, the alignment member 1230 may move from the first point P1 to the second point P2 to align the substrate W.

Referring to FIG. 5B, an alignment member 1230-1 may align the center of the substrate W according to rotation of the protruding pin 1231.

The alignment pin 1233 may be moved by a rotation method of the protruding pin 1231 from the first point P1 to the second point P2. That is, the alignment pin 1233 may be coupled to or integrally formed with a top surface of the protruding pin 1231, and as the protruding pin 1231 rotates around the vertical direction Z, the alignment pin 1233 may move from the first point P1 to the second point P2. In contrast, as the protruding pin 1231 rotates around the vertical direction Z, the alignment pin 1233 may move from the second point P2 to the first point P1.

In this case, an impact absorbing pad 1235 may be formed on a side surface of the alignment pin 1233. The impact absorbing pad 1235 may minimize impact applied to the substrate W when the alignment pin 1233 pushes and moves a side surface of the substrate W.

When the alignment pin 1233 moves between the first point P1 and the second point P2 due to rotation of the protruding pin 1231, the impact absorbing pad 1235 may be formed over the entire side surface of the alignment pin 1233.

Referring to FIG. 5C, an alignment member 1230-2 may align the center of the substrate W according to sliding of the alignment pin 1233.

The alignment pin 1233 may move in a sliding manner from the first point P1 to the second point P2. That is, the alignment pin 1233 may linearly move from first point P1 to the second point P2 along a line formed on a top surface of the protruding pin 1231. In this case, the protruding pin 1231 may be fixed to a top surface of the second chuck body 1210, and the alignment pin 1233 may move in a sliding manner on the top surface of the protruding pin 1231.

In this case, an impact absorbing pad 1236 may be formed on a side surface of the alignment pin 1233. The impact alignment pad 1236 may be formed only on a side surface of the alignment pin 1233 facing the substrate W. This is because, when the alignment pin 1233 moves between the first point P1 and the second point P2 in a sliding manner, a portion other than the side surface facing the substrate W may not contact the substrate W.

Because the substrate W is aligned to have the same axis as the center of the first chuck 1100 by the substrate support apparatus 1000 according to the disclosure, a bevel process performed on an outer portion of the substrate W may be easily performed.

Also, because a movable distance of the alignment pin 1233 is equal to or less than a diameter of the top surface of the protruding pin 1231, a range of movement of the alignment pin 1233 may be small. Accordingly, the substrate W may be aligned with the center of the first chuck 1100 more precisely.

After alignment of the substrate W is finished, the second chuck 1200 may be lowered by the height adjusting unit 1300. As the second chuck 1200 is lowered, contamination of the substrate W by the second chuck 1200 during a subsequent process performed on the substrate W may be prevented.

FIG. 7 is a plan view schematically illustrating a second chuck, according to embodiments. FIG. 8 is a plan view schematically illustrating a second chuck, according to embodiments.

Referring to FIG. 7, a second chuck 1201 may include a second chuck body 1211 and the alignment body 1230. The second chuck body 1211 may have a cylindrical shape extending in the vertical direction Z. In this case, a circular hole may be formed at the center of the second chuck body 1211. Accordingly, the second chuck body 1211 may have a donut shape when viewed in the vertical direction Z.

When the second chuck body 1211 has this shape, the second chuck 1201 may be easily coupled to the driving unit 1130 of the first chuck, and the number of alignment members 1230 formed on the second chuck body 1211 may also be arbitrarily increased or reduced.

On the other hand, referring to FIG. 8, a second chuck 1203 may include a second chuck body 1213 having an arm shape. That is, the second chuck 1203 may include a plurality of second chuck bodies 1213 having arm shapes. The second chuck body 1213 may have an arm shape extending in a horizontal direction.

When the second chuck 1203 includes the second chuck bodies 1213 having arm shapes, a volume of the second chuck 1203 may be optimized, and thus, costs required to manufacture the second chuck 1203 may be reduced. Also, because a space occupied by the second chuck 1203 in a chamber is reduced, the influence of the second chuck 1203 on the substrate W during a process may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A substrate support apparatus comprising:
a first chuck configured to support a substrate by contacting a bottom surface of the substrate; and
a second chuck configured to horizontally move the substrate by contacting a side surface of the substrate,
wherein the second chuck comprises:
a second chuck body coupled to the first chuck;
a plurality of protruding pins vertically protruding from an outer portion of a top surface of the second chuck body; and
an alignment pin vertically protruding from a top surface of each of the plurality of protruding pins,
wherein the plurality of protruding pins are located at a same horizontal distance from a center of the first chuck.

2. The substrate support apparatus of claim 1, wherein the alignment pin is configured to move between a first point and a second point on the top surface of the protruding pin,
wherein the second points on the top surfaces of the plurality of protruding pins are located at a same horizontal distance from the center of the first chuck.

3. The substrate support apparatus of claim 2, wherein the alignment pin moves between the first point and the second point due to a rotation of the protruding pin.

4. The substrate support apparatus of claim 2, wherein the alignment pin moves horizontally between the first point and the second point in a sliding manner on the top surface of the protruding pin.

5. The substrate support apparatus of claim 2, wherein the alignment pin moves the substrate by pushing a side surface of the substrate while moving from the first point to the second point.

6. The substrate support apparatus of claim 2, further comprising an impact absorbing pad formed on a side surface of the alignment pin.

7. The substrate support apparatus of claim 1, wherein the second chuck body has a cylindrical shape that vertically extends.

8. The substrate support apparatus of claim 1, wherein the second chuck body comprises a plurality of arms that extend horizontally.

9. The substrate support apparatus of claim 1, wherein the second chuck further comprises a height adjusting unit configured to vertically move the second chuck body.

10. The substrate support apparatus of claim 1, wherein three protruding pins are provided,
wherein the three protruding pins are located along vertices of a virtual equilateral triangle on the top surface of the second chuck body.

11. The substrate support apparatus of claim 1, wherein the first chuck is a vacuum chuck using vacuum to attach the bottom surface of the substrate.

12. A substrate support apparatus comprising:
a first chuck configured to support a substrate by contacting a bottom surface of the substrate;
a second chuck configured to horizontally move the substrate by contacting a side surface of the substrate, the second chuck comprising a second chuck body coupled to the first chuck, a plurality of protruding pins vertically protruding from an outer portion of a top surface of the second chuck body, and an alignment pin vertically protruding from a top surface of each of the plurality of protruding pins; and
a height adjusting unit configured to vertically move the second chuck,
wherein the plurality of protruding pins are located at a same horizontal distance from a center of the first chuck, and
the alignment pin is configured to move between a first point and a second point on the top surface of the protruding pin,
wherein the second points on the top surfaces of the plurality of protruding pins are located at a same horizontal distance from the center of the first chuck, and
the alignment pin moves the substrate by pushing a side surface of the substrate while moving from the first point to the second point.

13. The substrate support apparatus of claim 12, wherein the alignment pin moves between the first point and the second point due to rotation of the protruding pin.

14. The substrate support apparatus of claim 12, wherein the alignment pin moves horizontally between the first point and the second point in a sliding manner on the top surface of the protruding pin.

15. The substrate support apparatus of claim 14, further comprising an impact absorbing pad formed on a side surface of the alignment pin,
wherein the impact absorbing pad is formed only on a side surface of the alignment pin facing a side surface of the substrate.

16. The substrate support apparatus of claim 12, wherein the second chuck body has a cylindrical shape that vertically extends.

17. The substrate support apparatus of claim 12, wherein three protruding pins are provided,
wherein the three protruding pins are located along vertices of a virtual triangle on the top surface of the second chuck body.

18. A substrate support apparatus comprising:
a first chuck comprising a support plate configured to support a substrate and a driving unit configured to drive the support plate, the support plate contacting a bottom surface of the substrate;
a second chuck contacting a side surface of the substrate to horizontally move the substrate, the second chuck comprising a second chuck body coupled to the driving unit of the first chuck, a plurality of protruding pins vertically protruding from an outer portion of a top surface of the second chuck body, and an alignment pin vertically protruding from a top surface of each of the plurality of protruding pins; and
a height adjusting unit configured to vertically move the second chuck,
wherein the plurality of protruding pins comprise at least three protruding pins and are located at a same horizontal distance from a center of the first chuck, and
the alignment pin is configured to move between a first point and a second point on the top surface of the protruding pin,
wherein the second points on the top surfaces of the plurality of protruding pins are located at a same horizontal distance from the center of the first chuck, and
an impact absorbing pad is formed on a side surface of the alignment pin.

19. The substrate support apparatus of claim 18, wherein the alignment pin moves between the first point and the second point due to rotation of the protruding pin.

20. The substrate support apparatus of claim 18, wherein the alignment pin moves horizontally between the first point and the second point in a sliding manner on the top surface of the protruding pin.
